(19) United States
(12) Patent Application Publication
(10) Pub. No.: US 2014/0009004 A1
(43) Pub. Date: Jan. 9, 2014

(54) PORTABLE EMF SHIELD FOR LAPTOPS THAT PROTECTS ALL SURFACES OF THE LAPTOP

(71) Applicants: Isabelle Josephine Schroeder, Tarentum, PA (US); Maryellen Ann Schroeder, Tarentum, PA (US)

(72) Inventors: Isabelle Josephine Schroeder, Tarentum, PA (US); Maryellen Ann Schroeder, Tarentum, PA (US)

(21) Appl. No.: 13/541,764

(22) Filed: Jul. 4, 2012

(51) Int. Cl. H05K 9/00

(52) U.S. Cl. 307/326

(57) ABSTRACT

An electromagnetic field shielding device not only protects the lap of the user, but also their hands and face. The EMF shield has an EMF shield for the bottom of the laptop as well as a flexible, see-through, type-through EMF shield that extends over the screen and keyboard. The EMF shield of the present invention shields all areas of the laptop and protects the user from EMF radiation from laptops in the x, y and z axes, not merely a downward axis from the bottom of the laptop.

### BACKGROUND OF THE INVENTION

The present invention relates to laptop accessories and, more particularly, to a portable electromagnetic field (EMF) shield for a portable electronic device, such as a laptop computer or iPAD, that protects all surfaces of the electronic device.

Portable electronic devices, such as laptop computers and iPADs, emit electromagnetic fields. There is concern among laptop users that such EMFs could be harmful, especially from day-to-day exposure.

Conventional EMF shields have been designed to protect the lap of a user. Typically, such shields are designed as rigid surfaces that the user places in between their lap and the laptop computer. These convention EMF shields, however, do not protect the user from all surfaces of the laptop or iPAD. Electromagnetic fields can be emitted from the top (keyboard) side of the laptop, from the screen, and the like.

As can be seen, there is a need for an improved EMF shield for a laptop computer that can protect a user from electromagnetic fields emitted from all surfaces of the laptop.

### SUMMARY OF THE INVENTION

In one aspect of the present invention, a shielding device comprises a pouch having a pouch cavity formed therein; an insert fitting inside the pouch, the insert operable to block electromagnetic field radiation from passing therethrough; and a see-through shield member attached to the pouch and sized to wrap around an electronic device resting on the pouch.

In another aspect of the present invention, a shielding device for blocking electromagnetic field radiation emissions from a laptop computer comprises a pouch having a pouch cavity formed therein; an insert fitting inside the pouch, the insert operable to block electromagnetic field radiation from passing therethrough; a pouch flap adapted to close over the pouch cavity to retain the insert therein; a see-through shield member attached to the pouch and sized to wrap around an electronic device resting on the pouch; and one or more elastic bands adapted to retain the see-through shield member to the electronic device.

In a further aspect of the present invention, a method for protecting a user from electromagnetic radiation emissions from an electronic device comprises placing the electronic device on a pouch, the pouch having a cavity formed therein to hold an insert, the insert operable to block the electromagnetic radiation emissions from passing therethrough; and wrapping a see-through shield member, which is attached to and extends from the pouch, around the electronic device, covering a screen and a keyboard of the electronic device.

These and other features, aspects and advantages of the present invention will become better understood with reference to the following drawings, description and claims.

### BRIEF DESCRIPTION OF THE DRAWINGS

FIG. 1 is a perspective view of an EMF shield, in use, on a laptop computer, according to an exemplary embodiment of the present invention;

FIG. 2 is an exploded perspective view of an EMF shield fabric insert being inserted into a laptop shield fashion fabric pouch to create a base member of the EMF shield of FIG. 1;

FIG. 3 is a perspective view of the base member of FIG. 2 having its laptop shield fashion fabric pouch flap closed;

FIG. 4 is a perspective view showing the attachment of a see-through, finished edge EMF shield to the base member of FIG. 3;

FIG. 5 is a perspective view showing the placement of a laptop computer onto the base member of the EMF shield;

FIG. 6 is a perspective view showing the folding of the flexible see-through, finished edge EMF shield over and around the laptop;

FIG. 7 is a perspective view showing a laptop enclosed by the EMF shield of the present invention; and

FIG. 8 is an exploded view showing attachment members, such as elastic cords, used to secure the see-through, finished edge EMF shield onto the laptop computer.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides an electromagnetic field shielding device that not only protects the lap of the user, but also their hands and face. The EMF shield has an EMF shield for the bottom of the laptop or iPAD as well as a flexible, see-through, type-through EMF shield that extends over the screen and keyboard. The EMF shield of the present invention shields all areas of the laptop and protects the user from EMF radiation from laptops in the x, y and z axes, not merely a downward axis from the bottom of the laptop.

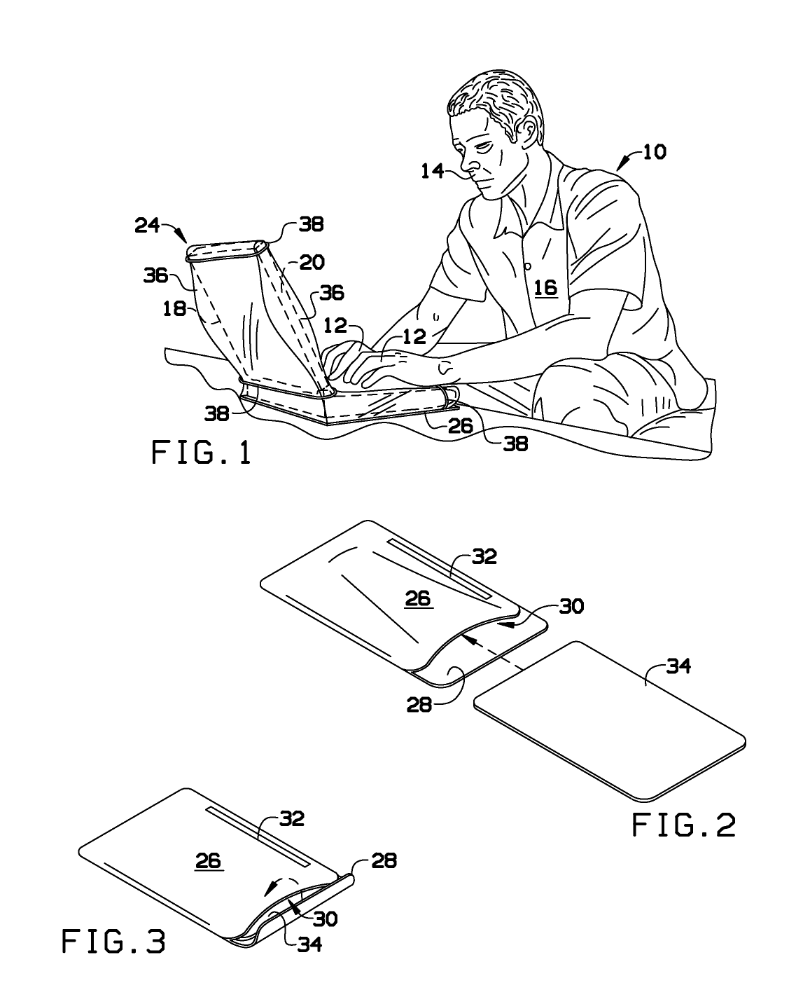

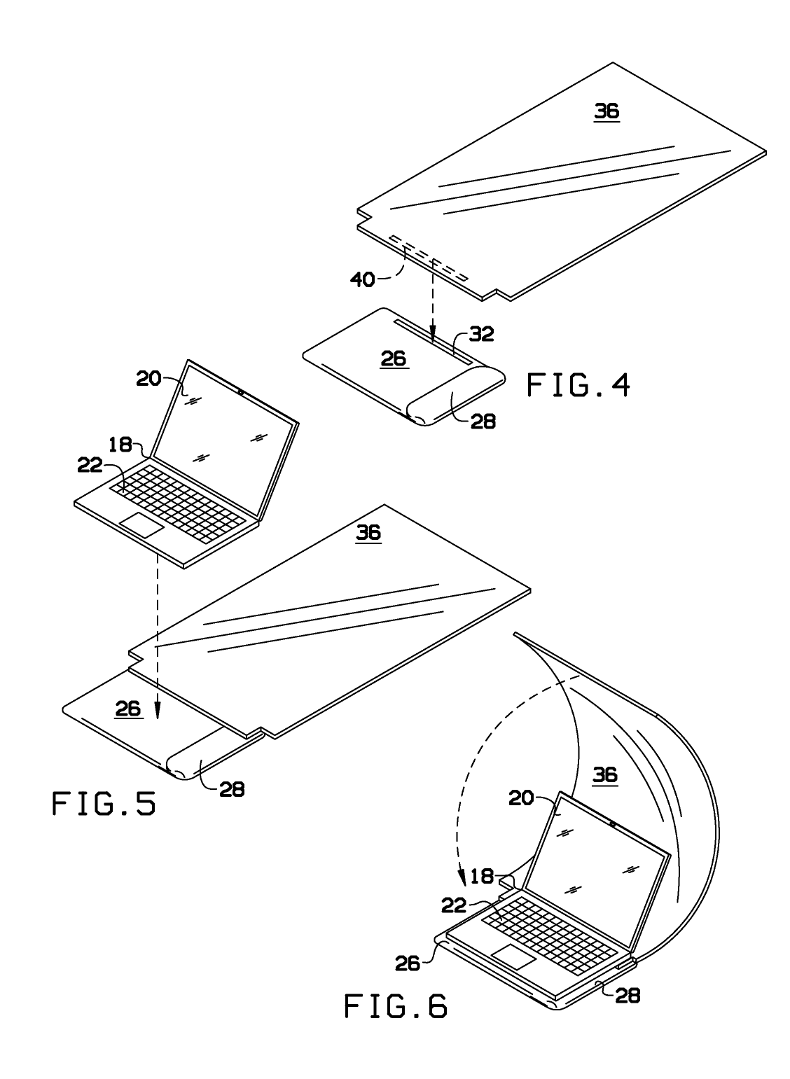

Referring now to FIGS. 1 through 8, a portable electronic device, such as a laptop 18, includes a screen 20 and a keyboard 22. A user 10 may work on the laptop 18, either with the laptop 18 on their lap, or with the laptop 18 in front of them. Even in the latter case, the user's face 14 and abdomen 16 may be subject to EMF radiation from the laptop 18. A laptop shield assembly 24 can help protect the user 10 and reduce or eliminate EMF radiation from reaching him or her during use of the laptop 18.

The base of the EMF shield assembly 24 can be made of a fashion fabric pouch 26 having a pouch shield cavity 30 formed therewithin. An EMF shield insert 34 can fit inside the pouch shield cavity 30. A fabric pouch flap 28 can close the shield cavity 30 once the EMF shield insert 34 is disposed therein. The flap 28 can simply be folded over to close the cavity 30, or a fastener (not shown) may be used, such as a snap, clip, hook and loop fastener (such as Velcro®), or the like. A pouch fastener 32, such as hook and loop material, can be disposed along one side of the pouch 26.

The pouch 26 can be made of various materials, typically a flexible fabric material, in a color and style that matches the user's taste. To clean the pouch 26, the insert 34 can be removed and the pouch 26 can be laundered in, for example, a washing machine.

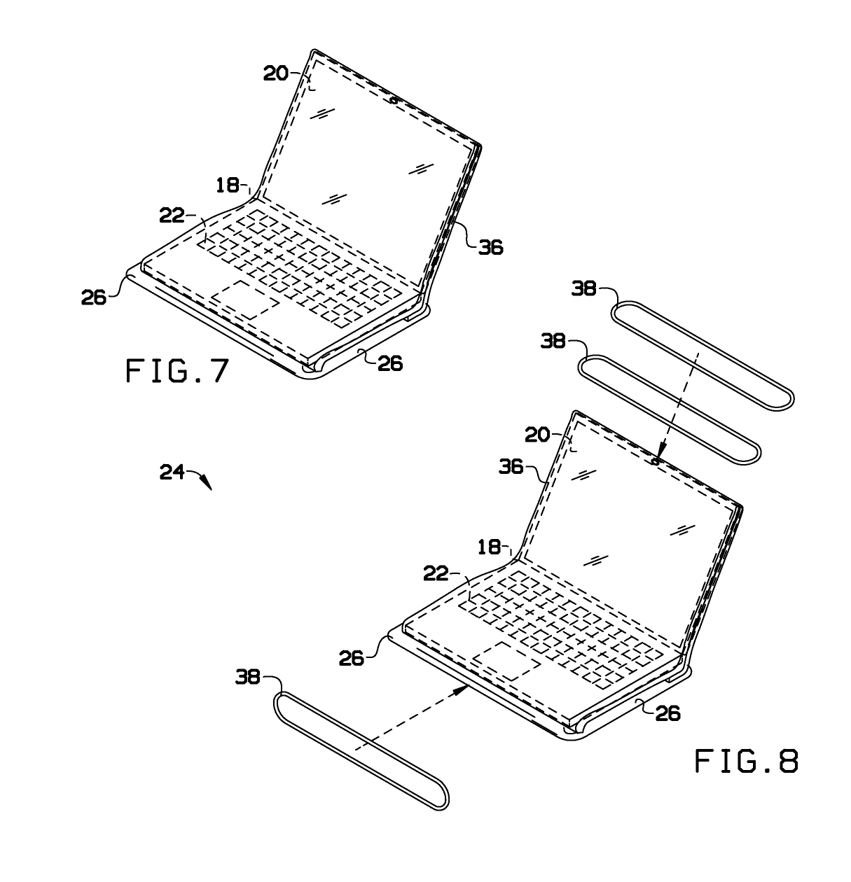

A see-through, type-through, finished edge EMF shield 36 may include a shield fastener 40 along one edge thereof, such as hook and loop material that can interlock with the pouch fastener 32. The shield 36 may be a flexible material that can wrap around the back of the screen 20, the front of the screen 20, and over the keyboard 22 of the laptop 18, as shown in FIGS. 6 and 7.

The laptop 18 can be used, as is, with the shield 36 disposed thereover. In some embodiments, elastic bands 38 can be used, typically from 2 to 4 elastic bands, to secure the shield 36 to the laptop 18.

The laptop shield assembly 24 can be attached to the laptop 18 in seconds. The laptop shield assembly 24 can shield much of the EMF radiation that emanates from the laptop, typically shielding over 99 percent of such EMF radiation.

While the drawings depict a laptop computer being shielded with the device of the present invention, other portable electronic devices may benefit from the shield assembly of the present invention.

It should be understood, of course, that the foregoing relates to exemplary embodiments of the invention and that modifications may be made without departing from the spirit and scope of the invention as set forth in the following claims.

What is claimed is:

1. A shielding device comprising:
a pouch having a pouch cavity formed therein;
an insert fitting inside the pouch, the insert operable to block electromagnetic field radiation from passing therethrough; and
a see-through shield member attached to the pouch and sized to wrap around an electronic device resting on the pouch.

2. The shielding device of claim 1, further comprising a pouch flap adapted to close over the pouch cavity to retain the insert therein.

3. The shielding device of claim 1, further comprising one or more elastic bands adapted to retain the see-through shield member to the electronic device.

4. The shielding device of claim 1, wherein the electronic device is a laptop computer.

5. The shielding device of claim 1, wherein the pouch is removably attached to the see-through shield member with one or more pieces of hook and loop fastener disposed on the pouch and the see-through shield member.

6. A shielding device for blocking electromagnetic field radiation emissions from a laptop computer, comprising:
a pouch having a pouch cavity formed therein;
an insert fitting inside the pouch, the insert operable to block electromagnetic field radiation from passing therethrough;
a pouch flap adapted to close over the pouch cavity to retain the insert therein;
a see-through shield member attached to the pouch and sized to wrap around an electronic device resting on the pouch; and
one or more elastic bands adapted to retain the see-through shield member to the electronic device.

7. The shielding device of claim 6, wherein the pouch is removably attached to the see-through shield member with one or more pieces of hook and loop fastener disposed on the pouch and the see-through shield member.

8. A method for protecting a user from electromagnetic radiation emissions from an electronic device, comprising:
placing the electronic device on a pouch, the pouch having a cavity formed therein to hold an insert, the insert operable to block the electromagnetic radiation emissions from passing therethrough; and
wrapping a see-through shield member, which is attached to and extends from the pouch, around the electronic device, covering a screen and a keyboard of the electronic device.

9. The method of claim 8, further comprising closing a pouch flap over the pouch cavity to retain the insert therein.

10. The method of claim 8, further comprising retaining the see-through shield member to the electronic device with one or more elastic bands.
